(19) United States
(12) Patent Application Publication
(10) Pub. No.: US 2004/0183192 A1
(43) Pub. Date: Sep. 23, 2004

(54) Semiconductor device assembled into a chip size package

(76) Inventors: Masashi Otsuka, Fujisawa-shi (JP); Chiaki Takubo, Tokyo (JP)

Correspondence Address: Finnegan, Henderson, Farabow,, Garrett & Dunner, L.L.P., 1300 I Street, N.W., Washington, DC, 20005-3315, US

(21) Appl. No.: 10/752,019

(22) Filed: Jan. 7, 2004

(30) Foreign Application Priority Data
Jan. 31, 2003 (JP) P2003-23815

(51) Int. Cl. H01L 23/48

(52) U.S. Cl. 257/734

(57) ABSTRACT

A first insulating film has a first planar surface as a lower surface. A first semiconductor chip is disposed on the first insulating film. A second insulating film is disposed on the first semiconductor chip and the first insulating film and has a second planar surface as an upper surface. A first wiring layer is disposed under the first planar surface. A second wiring layer is disposed on the second planar surface and electrically connected to the first semiconductor chip. A first conductive column penetrates the first insulating film and the second insulating film. A conductor penetrates the second insulating film.

### CROSS REFERENCE TO RELATED APPLICATIONS

This application is based upon and claims the benefit of priority from prior Japanese Patent Applications No. P2003-23815, filed on Jan. 31, 2003; the entire contents of which are incorporated herein by reference.

### BACKGROUND OF THE INVENTION

1. Field of the Invention

The present invention relates to a semiconductor device assembled into a high-density mounting package. In particular, the present invention relates to reductions in size and thickness of a mounting package of a semiconductor device.

2. Description of the Related Art

In recent years, as mounting packages for semiconductor devices used in a consumer apparatus, high-density chip size packages (CSP) have been actively developed. Of these high-density chip size packages, a stacked CSP called a system-in package (SiP) in which a plurality of semiconductor chips are stacked in the mounting package has also been actively developed. In the stacked CSP, a plurality of semiconductor chips are placed on a support substrate in piles, wired by wire bonding, and sealed by a resin. Therefore, the following two problems are posed. (1) The semiconductor chips must be stacked such that the wire bonding pads of all the semiconductor chips are exposed. For this reason, the chip size of one semiconductor chip disadvantageously restricts the other semiconductor chips in size. (2) Since a CSP is tested without testing respective semiconductor chips after resin sealing, the yield of the CSP becomes considerably low when the yield of the respective semiconductor chips is low. A so-called unknown good die (KGD) problem is posed.

Therefore, in Japanese Patent No. 3212127 and Japanese Patent Application No. 2001-68624, a method for merging electronic parts in a support substrate having a multi-layered wiring is proposed. In these methods, CSPs can also be tested in units of support substrates. However, these methods have the following constraints. That is, assembling processes for each semiconductor chip are required, and the packaging density cannot be increased.

### SUMMARY OF THE INVENTION

An aspect of the present invention inheres in a semiconductor device according to embodiments of the present invention. The semiconductor device includes a first insulating film having a first planar surface as a lower surface, a first semiconductor chip disposed on the first insulating film, a second insulating film disposed on the first semiconductor chip and the first insulating film and having a second planar surface as an upper surface, a first wiring layer is disposed under the first planar surface, a second wiring layer is disposed on the second planar surface and electrically connected to the first semiconductor chip, a first conductive column penetrating the first insulating film and the second insulating film, configured to electrically connect the first wiring layer to the second wiring layer, and a conductor penetrating the second insulating film configured to electrically connect the first semiconductor chip to the second wiring layer.

Another aspect of the present invention inheres in a semiconductor device according to embodiments of the present invention. The semiconductor device includes a conductive plate having a first planar surface as an upper surface, an adhesive layer disposed on the first planar surface, a first semiconductor chip disposed on the adhesive layer, a first insulating film disposed on the first semiconductor chip and the conductive plate and having a second planar surface as an upper surface, and a first wiring layer disposed on the second planar surface and configured to electrically connect to the first semiconductor chip.

Still another aspect of the present invention inheres in a method for manufacturing a semiconductor device according to embodiments of the present invention. The method includes adhering the entirety of a bottom surface of a semiconductor chip to a first insulating film, and adhering a second insulating film to the first insulating film and the entirety of an upper surface of the semiconductor chip, forming a first hole penetrating the second insulating film to expose the upper surface of the semiconductor chip, and forming a second hole penetrating the first insulating film and the second insulating film, burying a first conductor in the first hole, and burying a second conductor in the second hole, and forming a first wiring layer configured to electrically connect to the second conductor and disposed on a surface of the first insulating film, and forming a second wiring layer configured to electrically connect to the first conductor and the second conductor and disposed on a surface of the second insulating film.

Still another aspect of the present invention inheres in a method for manufacturing a semiconductor device according to embodiments of the present invention. The method includes adhering the entirety of a bottom surface of a semiconductor chip to a metal plate and adhering a first insulating film to the metal plate and the entirety of an upper surface of the semiconductor chip, forming a hole penetrating the first insulating film to expose the upper surface of the semiconductor chip, burying a first conductor in the hole, and forming a first wiring layer configured to electrically connect to the first conductor and disposed on a surface of the first insulating film.

### BRIEF DESCRIPTION OF DRAWINGS

FIG. 1A is an upper view of a semiconductor device according to a first embodiment.

FIG. 1B is a sectional view of the semiconductor device in an IB-IB direction in FIG. 1A.

FIGS. 2A to 2F are sectional views of the semiconductor device according to the first embodiment in course of manufacture.

FIG. 3 is a sectional view of a semiconductor device according to a second embodiment.

FIG. 4 is a sectional view of a semiconductor device according to a third embodiment.

FIG. 5 is a sectional view of a semiconductor device according to a fourth embodiment.

FIG. 6 is a sectional view of a semiconductor device according to a fifth embodiment.

FIG. 7A is an upper view of a semiconductor device according to a sixth embodiment.

FIG. 7B is a sectional view of the semiconductor device taken on line VIIB-VIIB in FIG. 7A.

FIGS. 8A to 8G are sectional views of the semiconductor device according to the sixth embodiment in course of manufacture.

FIG. 9 is a sectional view of a semiconductor device according to a seventh embodiment.

FIG. 10A is an upper view of a semiconductor device according to an eighth embodiment.

FIG. 10B is a sectional view of the semiconductor device taken on line XB-XB in FIG. 10A.

FIGS. 11A to 11E are sectional views of the semiconductor device according to the eighth embodiment in course of manufacture.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

(First Embodiment)

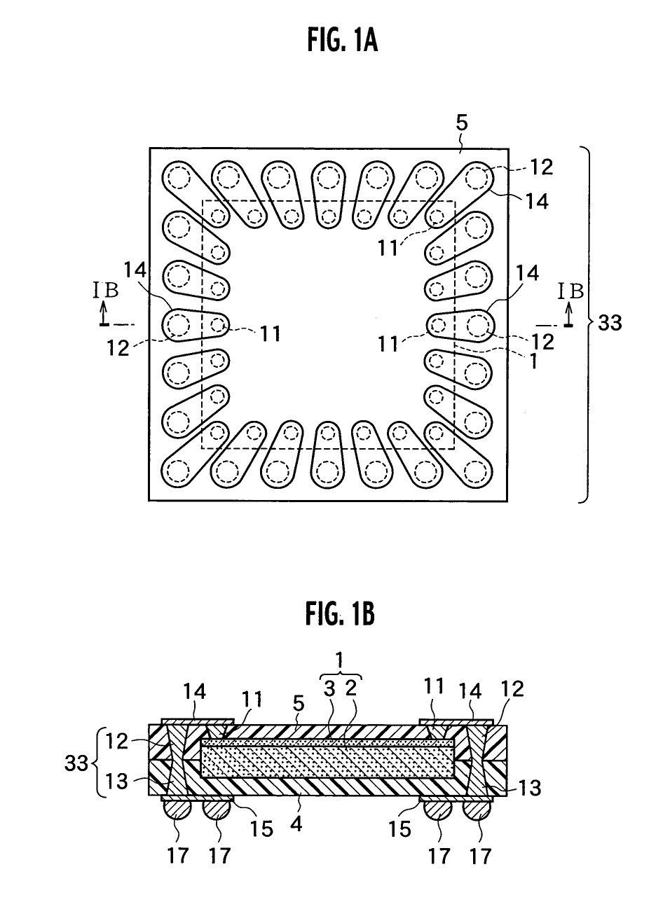

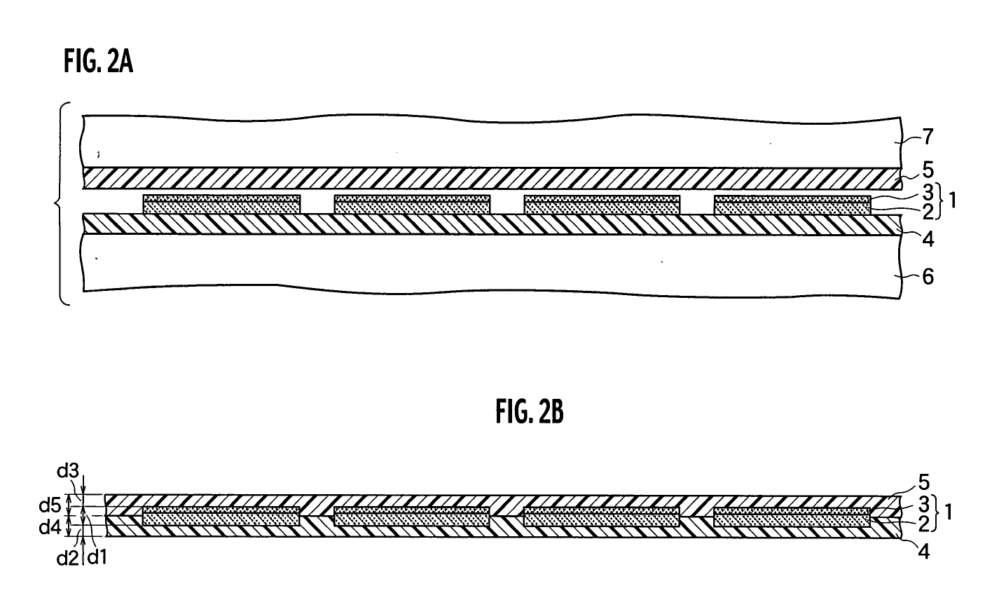

A semiconductor device 33 according to the first embodiment of the present invention, as shown in FIGS. 1A and 1B, has insulating films 4 and 5, wiring layers 14 and 15, a semiconductor chip 1, conductive columns 11 to 13, and conductive balls 17. The semiconductor device 33 constitutes a so-called package.

The insulating film 4 has a lower planar surface in a lower surface. The lower planar surface is larger than the lower surface of the semiconductor chip 1. The lower planar surface is arranged to extend from a lower portion under the semiconductor chip 1 to a distance further than the lower portion under a lateral outside of the semiconductor chip 1. The insulating film 4 is made of a resin. As the resin, a resin which can seal the semiconductor chip 1 is used. More specifically, a resin for stacking layers as a buildup substrate is used. A resin, for example, brand name: ABF available from Ajinomoto Co., Inc. can be used.

The wiring layer 15 can be formed under the lower planar surface of the insulating film 4. The wiring layer 15 is formed to extend from the lower portion under the semiconductor chip 1 to the lower portion under a lateral outside of the semiconductor chip 1. The wiring layer 15 is implemented by a rewiring pattern.

The top, bottom and side surfaces of the semiconductor chip 1 are sealed with the insulating films 4 and 5. The semiconductor chip 1 is arranged on the insulating film 4. The semiconductor chip 1 is implemented by a semiconductor substrate 1, and a semiconductor element forming region 2 is formed on the semiconductor substrate 1. The semiconductor element forming region 2 is provided with an electrode.

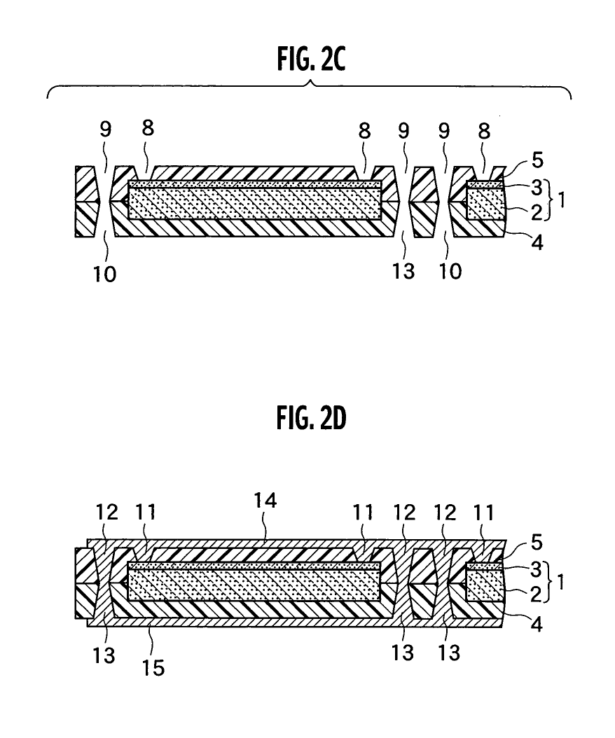

The insulating film 5 is formed on the semiconductor chip 1 and the insulating film 4. As the insulating film 5, the same resin as that of the insulating film 4 is used. The insulating film 5 has an upper planar surface in an upper surface. The upper planar surface is arranged to extend from the upper portion over the semiconductor chip 1 to the upper portion over a lateral outside of the semiconductor chip 1. As shown in FIG. 2B, a film thickness d2 of the insulating film 4 under the semiconductor chip 1 is equal to a film thickness d3 of the insulating film 5 above the semiconductor chip 1. A film thickness d4 of the insulating film 4 beneath the insulating film 5 is equal to a film thickness d5 of the insulating film 5 on the insulating film 4.

The wiring layer 14 is formed by a rewiring pattern. The rewiring pattern of the wiring layer 14 is electrically connected to an electrode of the semiconductor chip 1. The wiring layer 14 is formed on the upper planar surface of the insulating film 5 extending from the upper portion over the semiconductor chip 1 to the upper portion over a lateral outside of the semiconductor chip 1.

The conductive columns 12 and 13 constitute a via for a through electrode. The conductive column 12 penetrates the insulating film 5, and the conductive column 13 penetrates the insulating film 4. The conductive columns 12 and 13 are electrically connected to the wiring layers 14 and 15. The conductive columns 12 and 13 are arranged on a peripheral side of the semiconductor chip 1. The conductive columns 12 and 13 are arranged around the semiconductor device 33.

The conductive column 11 serving as a via penetrates the insulating film 4. The conductive column 11 is electrically connected to the electrode of the semiconductor chip 1 and the wiring layer 14.

The conductive balls 17 serving as a mounting ball is electrically connected to the wiring layer 15. The conductive column 11 is arranged around the semiconductor chip 1, as shown in FIG. 1A.

The semiconductor device according to the first embodiment can be used as a stand-alone thin CSP. More specifically, the semiconductor device, on its own, can independently test the semiconductor chip 1. In the semiconductor device according to the first embodiment, the semiconductor chips can be independently tested at low cost. The stacked CSP of the semiconductor device according to the first embodiment has an unrestricted chip size.

Since the semiconductor device has the wiring layers 14 and 15 on both the top and bottom surfaces, a plurality of semiconductor devices are stacked, and the wiring layers 14 and 15 of the plurality of semiconductor devices are connected to each other to make it possible to constitute a stacked CSP.

The thickness of a semiconductor device will be considered below. The thickness of the semiconductor chip 1 is 50 μm, and the thicknesses of the upper and lower insulating films 4 and 5 of the semiconductor chip 1 can be set at 30 to 40 μm. For this reason, the thickness of the semiconductor device is equal to the sum of these thicknesses, i.e., 110 to 130 μm. Therefore, a thin CSP can be achieved.

A method for manufacturing a semiconductor device according to the first embodiment of the present invention will be described below.

(a) As shown in FIG. 2A, a bonding device indicated by reference numerals 6 and 7 may be used, or a press roller may be used. The surfaces of a sample table 6 and a press table 7 of the bonding apparatus are planar surfaces. The insulating film 4 serving as a stacking resin film for a buildup support substrate is placed on the sample table 6 of the bonding device. A plurality of semiconductor chips 1 are placed on the insulating film 4 such that the entire bottom surfaces of the respective semiconductor chips 1 are in contact with the insulating film 4. The insulating film 5 is placed on the plurality of the semiconductor chips 1 such that the entire top surfaces of the respective semiconductor chips 1 are in contact with the insulating film 5. As the insulating film 5, an insulating film made of the same material as that of the insulating film 4 and having a film thickness equal to that of the insulating film 4 is used. The press table 7 of the bonding device is arranged on the insulating film 5.

(b) The insulating films 4 and 5 and the semiconductor chips 1 are compressed between the sample table 6 and the press table 7 of the bonding device. In this manner, as shown in FIG. 2B, the semiconductor chips 1 are laminated with the insulating films 4 and 5 from both top and bottom surfaces of the semiconductor chips 1. The semiconductor chips 1 and the insulating films 4 and 5 are integrated with each other. The entire bottom surfaces of the semiconductor chips 1 can be adhered to the insulating film 4. The insulating film 5 can be adhered to the entire top surfaces of the semiconductor chips 1 and the insulating film 4.

Reference symbol d1 denotes the thickness of the semiconductor chip 1. Reference symbol d2 denotes the film thickness of the insulating film 4 on which the semiconductor chip 1 is formed. Reference symbol d4 denotes the film thickness of the insulating film 4 on which no semiconductor chip 1 is formed. Reference symbol d3 denotes the film thickness of the insulating film 5 on which the semiconductor chip 1 is formed. Reference symbol d5 denotes the film thickness of the insulating film 5 on which no semiconductor chip 1 is formed. The interval (d1+d2+d3) between the lower surface of the insulating film 4 and the upper surface of the insulating film 5 between which the semiconductor chip 1 is formed is set to be equal to the interval (d4+d5) between the lower surface of the insulating film 4 and the upper surface of the insulating film 5 between which no semiconductor chip 1 is formed. This is because high compression stress acts on the insulating film 4 immediately below the semiconductor chip 1 and the insulating film 5 immediately above the semiconductor chip 1 at the time of compression, and the insulating films 4 and 5 are transformed by the compression stress to relieve the compression stress. The film thickness d2 of the insulating film 4 where the semiconductor chip 1 is formed is thinner than the film thickness d4 of the insulating film 4 where no semiconductor chip 1 is formed. The film thickness d3 of the insulating film 5 where the semiconductor chip 1 is formed is thinner than the film thickness d5 of the insulating film 5 where no semiconductor chip 1 is formed. In order to enhance the transformation, the compression stress is increased by the press table 7. In order to increase the compression stress, the press roller has an advantage over the press table 7. In order to enhance the transformation, the fluid properties of the insulating films 4 and 5 may be improved. For this purpose, the temperatures of the insulating films 4 and 5 may be increased.

As the insulating film 5, an insulating film made of the same material as that of the insulating film 4 and having a film thickness equal to that of the insulating film 4 is used, and the film thickness d3 of the insulating film 5 where the semiconductor chip 1 is formed is equal to the film thickness d2 of the insulating film 4 where the semiconductor chip 1 is formed. Similarly, the film thickness d5 of the insulating film 5 and the film thickness d4 of the insulating film 4 are equal to each other at a position where no semiconductor chip 1 is formed. In this manner, the variations in thickness of the insulating films 4 and 5 can be made equal to each other, so that the vector of residual stress can be generated in plane symmetry with respect to the semiconductor chip 1. In this manner, no warpage is generated in the semiconductor chip 1.

(c) Resists are coated on both upper and lower surfaces of the resultant structure and patterned. The insulating films 4 and 5 are etched by using the patterned resists as masks. As shown in FIG. 2C, holes 8 to 10 serving as via holes are formed. The holes 8 to 10 can be formed in the same manner as in a conventional buildup process. The hole 8 penetrates the insulating film 5. The hole 8 exposes the top surface of the semiconductor chip 1 to the air. The hole 9 penetrates the insulating film 5. The hole 10 penetrates the insulating film 4. The hole 9 is formed immediately above the hole 10. In this manner, through electrodes can be formed in the holes 9 and 10.

(d) A conductive film is formed on the exposed surface by a plating method. For this reason, as shown in FIG. 2D, the conductive column 11 can be buried in the hole 8. Similarly, the conductive column 12 can be buried in the hole 9. The conductive column 13 can be buried in the hole 10. In addition, the wiring layer 15 can be formed on the lower surface of the insulating film 4. The wiring layer 14 can be formed on the upper surface of the insulating film 5. Since the formed conductive films are continuous films, the conductive columns 12 and 13 are electrically connected to each other. Similarly, the wiring layer 15 is electrically connected to the conductive column 13. The wiring layer 14 and the conductive column 12 are electrically connected to each other. The wiring layer 14 and the conductive column 11 are electrically connected to each other.

(e) Resists are coated on both upper and lower surfaces of the resultant structure and patterned. The wiring layers 14 and 15 are etched by using the patterned resists as masks. As shown in FIG. 2E, the wiring layers 14 and 15 having the patterned wiring layers can be formed.

The wiring patterns of the wiring layers 14 and 15 are formed by a semi-additive method in principle. This process will be described below. A thin copper foil is formed on the exposed surface by an electroless plating method. In this manner, electric conductivity in the electrolytic plating which will be performed later is assured. Electrolytic plating is conducted, and negative masks of the wiring layers 14 and 15 are formed by the resist films. The conductive columns 11 to 13 serving as via plugs and the wiring layers 14 and 15 patterned in the inverted patterns of the negative masks are formed. The resist films are peeled. The thin copper foil is removed by an etch back method.

(f) The insulating films 4 and 5 are cut at a cut line 16, and as shown in FIG. 2F, the plurality of semiconductor chips 1 are separated into independent pieces or chips.

(g) Finally, as shown in FIGS. 1A and 1B, the conductive balls 17 for an external electrode are formed under the wiring layer 15. The separation of the plurality of semiconductor chips 1 into independent pieces and the formation of the conductive ball 17 may be performed in a random order.

In the method for manufacturing a semiconductor device according to the first embodiment, a plurality of processes such as a buildup support substrate manufacturing process, a bump process, and an assembling process (flip chip or resin sealing) which are separately performed in the prior art can be performed one time for a plurality of units of sheets of the stacked insulating films 4 and 5 having a plurality of semiconductor chips 1. In this manner, the productivity, i.e., the yield of semiconductor devices is considerably improved.

In a method for manufacturing a semiconductor device according to the first embodiment, in the process of stacking the insulating films 4 and 5, i.e., in the buildup support substrate manufacturing process, the semiconductor chip 1 is considered to be buried between the insulating films 4 and 5. Therefore, the conventional buildup support substrate manufacturing process can be utilized for the stacked films made of the insulating films 4 and 5 between which the semiconductor chip 1 is buried. In contrast to the conventional buildup support substrate manufacturing process, in the method for manufacturing a semiconductor device according to the first embodiment, a core support substrate of the buildup support substrate is not necessary, or the stacked films made of the insulating films 4 and 5 between which the semiconductor chip 1 is buried can be considered to correspond to the assembled buildup support substrate and constitute a core support substrate of a buildup support substrate. More specifically, the manufacturing process of a core support substrate, or the manufacturing process of a core support substrate and the assembling process of a buildup support substrate are simultaneously performed, so that the number of processes of the method for manufacturing a semiconductor device can be decreased. Since semiconductor devices are manufactured in units of sheets, the assembling cost can be reduced.

In the method for manufacturing a semiconductor device according to the first embodiment, semiconductor chips can be separately tested at low cost. In the method for manufacturing a semiconductor device according to the first embodiment, a stacked CSP can be manufactured without restricting chip size.

Since a conventional core support substrate is not present, the thickness of a semiconductor device depends on the thicknesses of the semiconductor chip 1 and the insulating films 4 and 5. In this manner, the thickness of the semiconductor device can be set within the range of 110 to 130 μm. In addition, since the insulating films 4 and 5 constitute a vertically symmetrical structure with respect to the semiconductor chip 1, warpage caused by the difference between expansion coefficients of the semiconductor chip 1 and the insulating films 4 and 5 can be prevented.

(Second Embodiment)

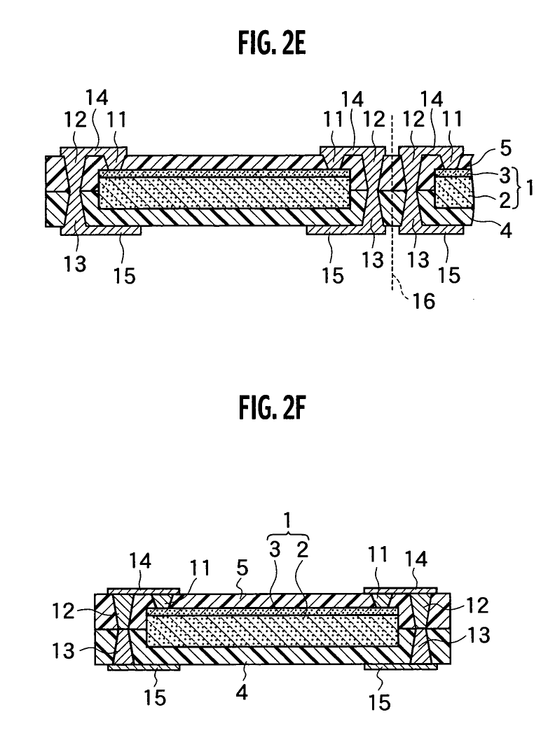

A semiconductor device according to the second embodiment, as shown in FIG. 3, provides semiconductor devices 33 and 34 having the same configuration as the chip 33 of the first embodiment. The semiconductor devices 33 and 34 constitute a so-called package, and constitute a stacked multi-chip module.

The semiconductor device 34 is arranged as a layer of the semiconductor device 33. Conductive balls 47 of the semiconductor device 34 are arranged on a wiring layer 14 of the semiconductor device 33 and electrically connected to the wiring layer 14. The conductive ball 47 is arranged under a wiring layer 15 of the semiconductor device 34 and electrically connected to the wiring layer 15. A semiconductor chip 1 of the semiconductor device 33 and a semiconductor chip 1 of the semiconductor device 34 may have the same structures and the same functions or different structures and different functions. In particular, the semiconductor chips 1 may be different from each other in size. The number of semiconductor devices 33 and 34 is not limited to two. Three or more semiconductor devices may be stacked.

The semiconductor devices 33 and 34 are tested before stacking. As stacked layers, the semiconductor devices 33 and 34 which pass the test are used. Therefore, the yield of stacked semiconductor devices can be increased.

(Third Embodiment)

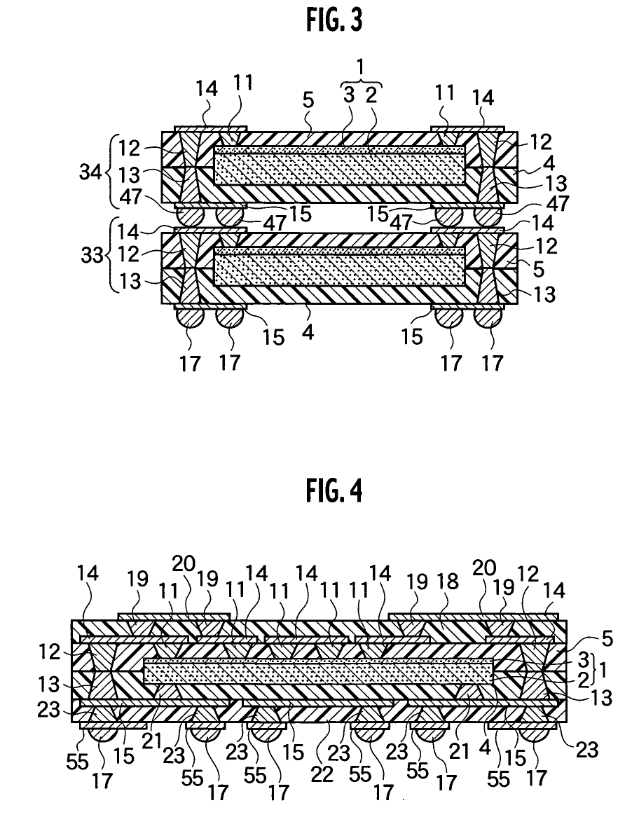

A semiconductor device according to the third embodiment of the present invention, as shown in FIG. 4, has a structure in which insulating films 18 and 22, a wiring layer 20, and conductor columns 19 and 23 are added to the semiconductor device 33 according to the first embodiment.

The insulating film 22 is formed under an insulating film 4 and a wiring layer 15. The insulating film 22 has a lower planar surface in a lower surface.

The insulating film 18 is formed on an insulating film 5 and a second wiring layer 14. The insulating film 18 has an upper planar surface in an upper surface. The film thickness of the insulating film 22 is constant regardless of the presence/absence of the semiconductor chip 1 above the insulating film 22. The film thickness of the insulating film 18 is constant regardless of the presence/absence of the semiconductor chip 1 under the insulating film 18. The film thicknesses of the insulating films 18 and 22 are equal to each other. This equal thickness can also prevent the semiconductor chip 1 from being warped. For this purpose, as the insulating films 18 and 22, films made of the same material and having equal film thicknesses are used. These films are simultaneously adhered to each other to have the same adhesive condition. In this manner, the temperature and pressure of the insulating film 18 in the adhesion can be made equal to those of the insulating film 22.

The wiring layer 20 is formed on the upper planar surface of the insulating film 18. The wiring layer 20 is electrically connected to the wiring layer 14.

The conductive column 19 penetrates the insulating film 18. The conductive column 19 is electrically connected to the wiring layers 14 and 20. The conductor column 23 penetrates the insulating film 22. The conductor column 23 is electrically connected to the wiring layer 15 and the conductive ball 17.

The semiconductor device according to the third embodiment can be completed such that buildup processes are simultaneously performed for both the upper and lower surfaces in the method for manufacturing a semiconductor device according to the first embodiment. The semiconductor device according to the third embodiment has a multi-layered wiring structure having three layers, i.e., the wiring layers 14, 15, and 20. The number of wiring layers can be increased as needed.

(Fourth Embodiment)

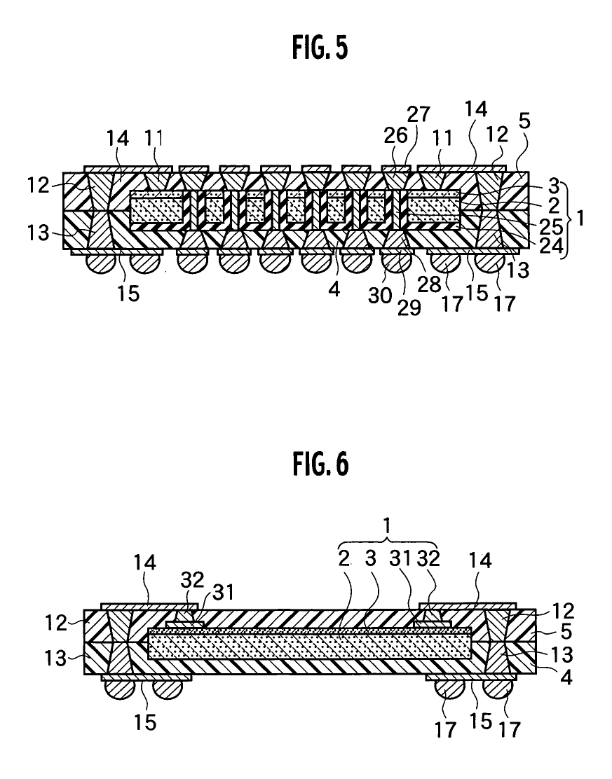

A semiconductor device according to the fourth embodiment of the present invention, as shown in FIG. 5, has a structure in which conductor columns 25, 26, and 28 which penetrate a semiconductor chip 1 and which are electrically connected to wiring layers 14 and 15 are added to the semiconductor device 33 according to the first embodiment.

The semiconductor chip 1 has, in addition to a semiconductor substrate 2 and a semiconductor element forming layer 3, a conductive column 25 serving as a through plug and an insulating film 24. The conductive column 25 extends from the top surface of the semiconductor substrate 2 to the bottom surface thereof. A conductive column 26 is arranged immediately above the conductive column 25. A conductive column 28 is arranged immediately below the conductive column 25. The conductive column 25 is electrically connected to the conductive columns 26 and 28. The insulating film 24 is formed between the semiconductor substrate 2 and the conductive column 25. On the conductive column 26, a wiring layer 27 is formed at the same level as that of the wiring layer 14. Under the conductive column 28, a wiring layer 29 is formed at the same level as that of the wiring layer 15. A conductive ball 30 is arranged under the wiring layer 29. The shape of the conductive ball 30 is the same as that of the conductive ball 17.

In this manner, on the entire top surface and the entire bottom surface of the semiconductor device, electrodes 27, 29 can be arranged. For this purpose, holes for via holes may be formed from both the upper and lower surfaces of the semiconductor device such that the electrodes 27, 29 can be connected to the conductive column 25 from both top and bottom surfaces of the semiconductor chip 1. Electrodes are arranged on the entire upper surface and the entire lower surface of the semiconductor device, so that a large number of pins can be assured in proportion to a package size, and improvement in mounting density can be expected.

The conductive column 25 is shaped by a pre-process (Cu-wiring plating) of the semiconductor chip 1. Since the conductive column 25 is very close to the semiconductor element forming region 3, the wiring length can be considerably reduced by directly drawing electrodes from the conductive columns 26 and 28.

For example, a case in which two semiconductor chips 1 each having 10 square millimeters are stacked to connect semiconductor elements arranged at the centers of the semiconductor chips 1 to each other by wire will be considered. When the conductive columns 12 and 13 are arranged around the semiconductor chip 1, at least 5 mm+5 mm (two-fold of a half of the length of the semiconductor chip 1)+0.1 mm (thickness of the semiconductor device 33)+0.2 mm (length from one end of the semiconductor chip 1 to the conductive columns 12 and 13) are required, the total wiring length being 10.3 mm. On the other hand, according to the semiconductor device of the fourth embodiment, since the two-fold of a half of the length of the semiconductor chip 1 can be omitted, the total wiring length is 0.3 mm. In this manner, the wiring length can be considerably shortened, and an inductance between wires can be reduced. The semiconductor device according to the fourth embodiment can be applied to a device which can be operated at a high speed.

(Fifth Embodiment)

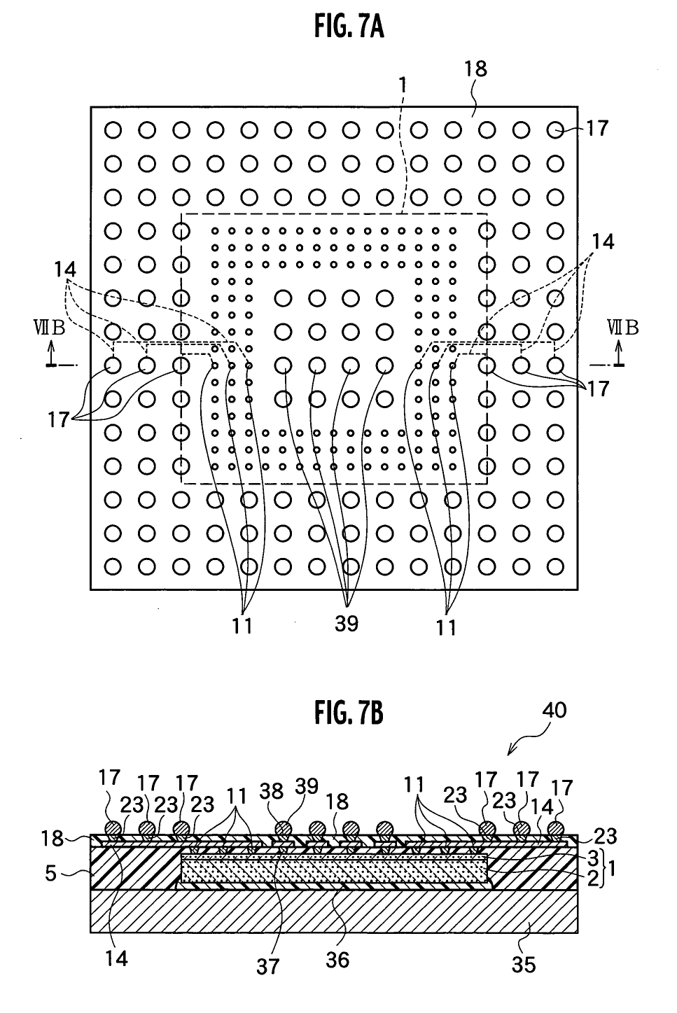

A semiconductor device according to the fifth embodiment of the present invention, as shown in FIG. 6, has a bump 31 in place of the conductive column 11 unlike the semiconductor device 33 according to the first embodiment.

The semiconductor chip 1 has, in addition to a semiconductor substrate 2 and a semiconductor element forming layer 3, a bump 32 serving as a conductive column. The semiconductor element forming layer 3 has an electrode pad 31 on the top surface thereof. The bump 32 is arranged on the electrode pad 31, and is electrically connected to the electrode pad. The bump 32 penetrates an insulating film 5 and is arranged under a wiring layer 14. The bump 32 is electrically connected to the wiring layer 14.

In the semiconductor device according to the fifth embodiment, before the semiconductor chip 1 and the insulating films 4 and 5 are laminated and integrated with each other, the bump 32 is formed on the electrode pad 31 of the semiconductor chip 1. In the laminating, high compression stress is generated on the insulating film 5 located immediately above the bump 32, the insulating film 5 immediately above the bump 32 is removed to expose the upper portion of the bump 32. The bump 32 may be a stud bump or a plating bump. In the semiconductor device according to the fifth embodiment, plating speeds of the conductive columns 12 and 13 need not be adjusted to simultaneously finish burying processes when the conductive columns 12 and 13 are formed by electrolytic plating. Time for the electrolytic plating for forming the wiring layers 14 and 15 and the conductive columns 12 and 13 can be shortened. In this manner, a process window for the electrolytic plating can be widened, and process management can be easily conducted.

(Sixth Embodiment)

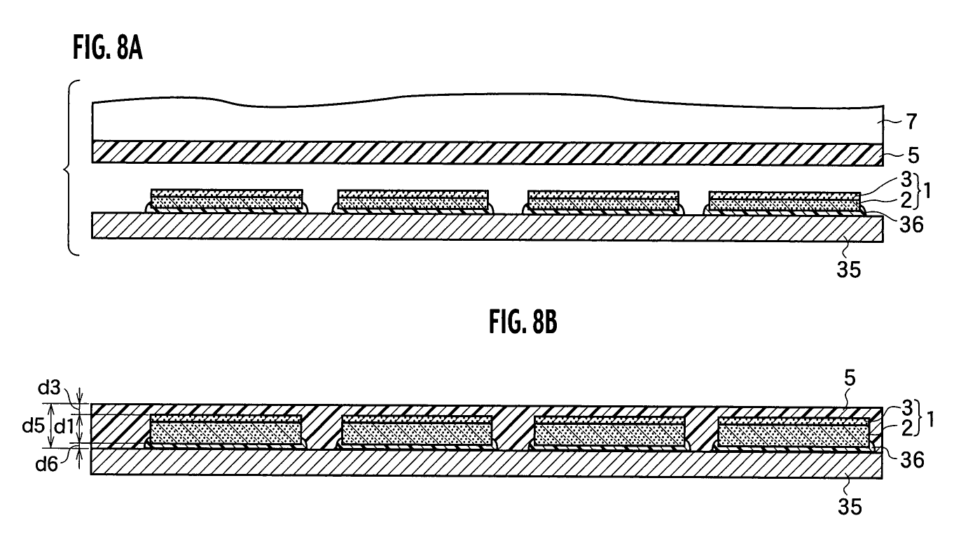

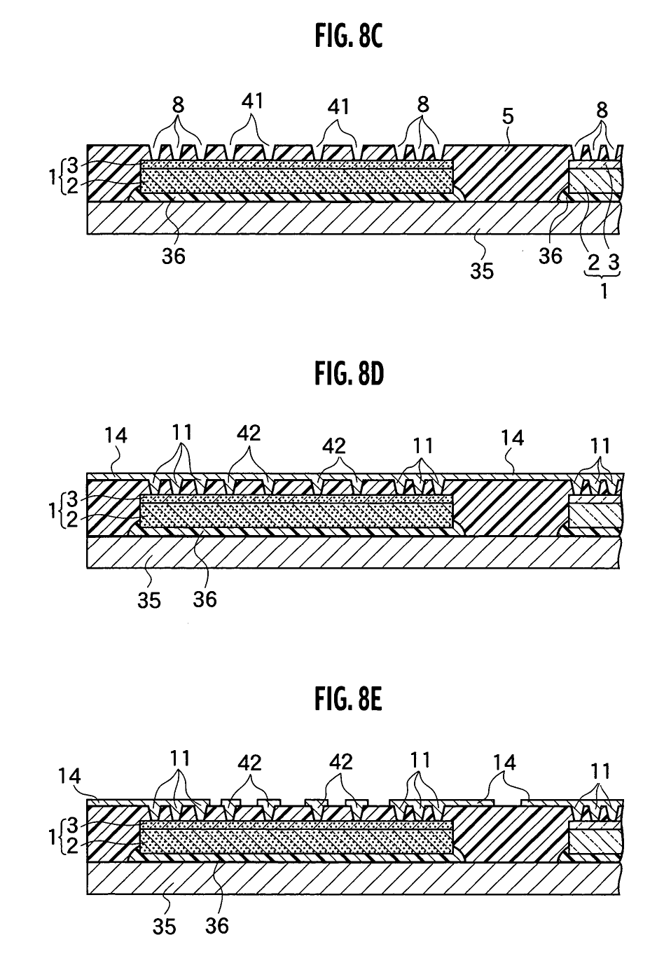

A semiconductor device according to the sixth embodiment of the present invention, as shown in FIGS. 7A and 7B, has a conductive plate 35, an adhesive layer 36, a semiconductor chip 1, insulating films 5 and 18, a wiring layer 14, a conductor column 23, and a conductive ball 17.

The conductive plate 35 has an upper planar surface in an upper surface. The conductive plate 35 requires a predetermined strength such that the wiring layer 14 is formed on one plane. However, in the steps in manufacturing the semiconductor device, the strength of the conductive plate 35 is enough to form the wiring layer 14 on one plane. In order to assure the strength of the semiconductor device in use, a heat-radiating fin or a heat sink is fixed to the lower side of the conductive plate 35. For this reason, the conductive plate 35 may have a small thickness such that the conductive plate 35 and the insulating films 5 and 18 are easily simultaneously cut. As the conductive plate 35, a so-called conductive foil may be used.

The adhesive layer 36 is formed on the upper planar surface of the conductive plate 35. The semiconductor chip 1 is arranged on the adhesive layer 36. The insulating film 5 is formed on the semiconductor chip 1 and the conductive plate 35. The insulating film 5 has an upper planar surface in an upper surface. This upper planar surface is also provided above a lateral outside of the semiconductor chip 1.

The wiring layer 14 is formed on the upper planar surface of the insulating film 5. The wiring layer 14 is electrically connected to the semiconductor chip 1. The insulating film 18 is formed on the wiring layer 14 and the insulating film 5. The conductive column 23 penetrates the insulating film 18. The conductive column 23 is electrically connected to the wiring layer 14 and the conductive ball 17. The conductive ball 17 is electrically connected to the wiring layer 14.

The semiconductor device according to the first embodiment is preferably applied to a semiconductor chip 1 in a region having a small number of pins. However, the semiconductor device according to the sixth embodiment is preferably applied to a semiconductor chip 1 in a multipin region, that is, a region having a large number of pins. In the semiconductor device according to the sixth embodiment, the bottom surface of the semiconductor chip 1 opposing the semiconductor element forming region 3 is sealed with the conductive plate 35, such as a metal plate, in place of an insulating film. Since the conductive plate 35 is a hard plate, the rigidity of the package of a semiconductor device can be assured, and a semiconductor device the size of which does not depend on the chip size of the semiconductor chip 1 and is larger than the chip size can be manufactured. For this reason, a large-size multipin package which can be applied to a semiconductor chip 1 in a multipin region can be provided.

A large amount of heat generated by the semiconductor chip 1 in the multipin region can be radiated through the conductive plate 35, and the heat resistance of the semiconductor device can be reduced. The conductive plate 35 functions as a heat-radiating plate or a heat sink.

Therefore, the material of the conductive plate 35 is desirably copper (Cu) or a copper alloy when greater importance is given to heat radiation. When heat radiation is not necessary, and when only a large number of conductive balls 17 serving as external pins are desired, and when a fan-out structure in which a package size is larger than a chip size is desired, as the conductive plate 35, an inexpensive aluminum alloy plate may be used, or a ceramic plate may be used to make the coefficient of linear expansion of the conductive plate 35 equal to that of the semiconductor chip 1.

A method for manufacturing a semiconductor device according to the sixth embodiment of the present invention will be described below.

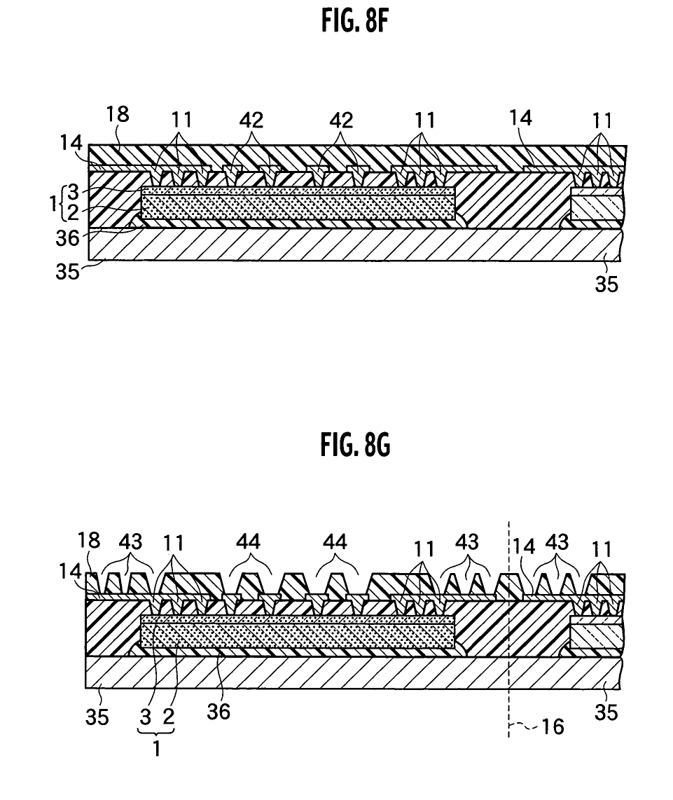

(a) As shown in FIG. 8A, a bonding device 7 is used. The surface of a press table 7 of the bonding apparatus is a planar surface. A plurality of semiconductor chips 1 are placed on a metal plate 35 such that the entire bottom surfaces of the respective semiconductor chips 1 are in contact with the metal plate 35. The insulating film 5 is placed on the plurality of semiconductor chips 1 such that the entire top surfaces of the semiconductor chips 1 are in contact with the insulating film 5. As the insulating film 5, an insulating film having the same material and film thickness as that of the insulating film 4 is used. The press table 7 of the bonding device is arranged above the insulating film 5.

(b) The insulating film 5 and the semiconductor chip 1 are compressed between the metal plate 35 and the press table 7 of the bonding device. When the metal plate 35 is warped by this compression, a sample table which can fix the metal plate 35 while keeping the metal plate 35 flat may be arranged under the metal plate 35. As shown in FIG. 8B, the semiconductor chip 1 is laminated with the metal plate 35 and the insulating film 5. The metal plate 35, the semiconductor chip 1, and the insulating film 5 are integrated with each other. The entire bottom surface of the semiconductor chip 1 can be adhered to the metal plate 35. The insulating film 5 can be adhered to the entire top surface of the semiconductor chip 1 and the metal plate 35.

Reference symbol d6 denotes the thickness of the adhesive layer 36. An interval (d1+d3+d6) between the upper surface of the metal plate 35 and the upper surface of the insulating film 5 at a position where the semiconductor chip 1 is formed is equal to that at a position (d5) where no semiconductor chip 1 is formed. This is because high compression stress acts on the insulating film 5 immediately above the semiconductor chip 1, and the insulating film 5 is transformed to moderate the compression stress, as discussed with reference to the first embodiment. The film thickness d3 of the insulating film 5 where the semiconductor chip 1 is formed is thinner than the film thickness d5 of the insulating film 5 where no semiconductor chip 1 is formed.

(c) The insulating film 5 and a resist are coated on the resultant structure and patterned. The insulating film 5 is etched by using the patterned resist as a mask. As shown in FIG. 8C, holes 8 and 41 serving as via holes are formed. The holes 8 and 41 penetrate the insulating film 5. The holes 8 and 41 expose the top surface of the semiconductor chip 1 to the air.

(d) A conductive film is formed on the exposed top surface by a plating method. For this reason, as shown in FIG. 8D, the conductive columns 11 and 42 can be buried in the holes 8 and 41. The wiring layer 14 can be formed on the upper surface of the insulating film 5. Since the formed conductive films are continuous films, the wiring layer 14 and the conductive columns 11 and 42 are electrically connected to each other.

(e) A resist is coated on the wiring layer 14 and patterned. The wiring layer 14 is etched by using the patterned resist as a mask. As shown in FIG. 8E, the wiring layer 14 having the patterned wiring layer can be formed. The wiring layer 14 may be formed by a semi-additive method.

(f) As shown in FIG. 8F, the insulating film 18 is adhered to the upper surface of the wiring layer 14. As shown in FIG. 8G, holes 43 and 44 are formed in the insulating film 18 above the wiring layer 14. The insulating films 5 and 18 and the conductive plate 35 are cut at a cut line 16 to separate the plurality of semiconductor devices into independent pieces.

(g) Finally, as shown in FIGS. 7A and 7B, conductive columns 23 and 38 are formed in the holes 43 and 44, respectively, and conductive balls 17 are formed on the conductive columns 23 and 38. The separation of the plurality of semiconductor chips 1 into independent pieces and the formation of the conductive columns 23 and 38 and the conductive ball 17 may be performed in random order.

In the method for manufacturing a semiconductor device according to the sixth embodiment, a plurality of processes such as a buildup support substrate manufacturing process, a bump process, an assembling process (flip chip or resin sealing), and a heat-radiation plate building process, which are separately performed in the prior art, can be performed only once on all the units or devices of the sheets of devices, each obtained by stacking the metal plate 35 having a plurality of semiconductor chips 1 and the insulating film 5. In this manner, the productivity, i.e., the yield of semiconductor devices is considerably improved.

(Seventh Embodiment)

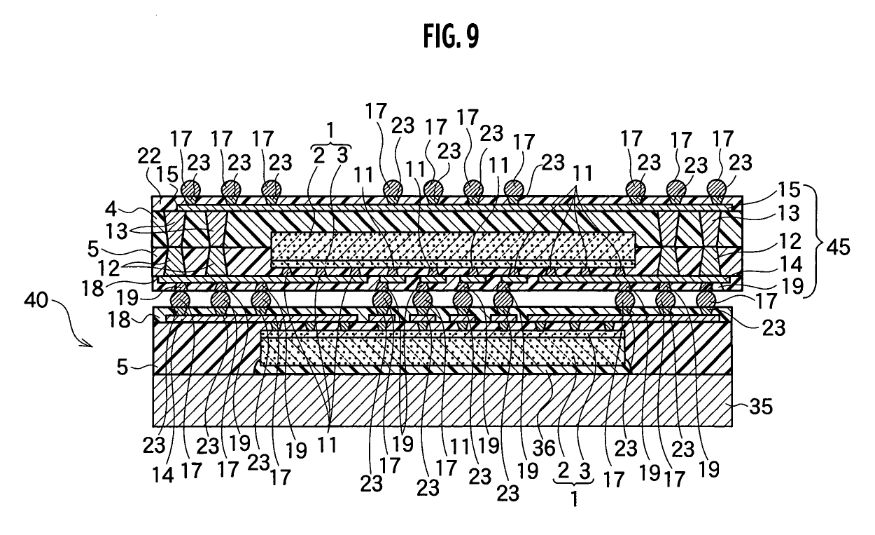

A semiconductor device according to the seventh embodiment of the present invention, as shown in FIG. 9, includes a semiconductor device 40 of the sixth embodiment and a semiconductor device 45 of one of the first to third embodiments. Each of the semiconductor devices 40 and 45 constitutes a so-called package, and a stacked multi-chip module is constituted by the semiconductor devices 40 and 45.

The semiconductor device 45 is arranged as a layer on the semiconductor device 40. The conductive ball 17 of the semiconductor device 40 is arranged under a conductive column 19 of the semiconductor device 45 and is electrically connected to the conductive column 19. The conductive column 19 of the semiconductor device 45 is arranged under the wiring layer 14 of the semiconductor device 45 and is electrically connected to the wiring layer 14. The number of semiconductor devices 40 and 45 is not limited two. Three or more semiconductor devices may be stacked.

The semiconductor devices 40 and 45 are tested before stacking. As the stacked layers, the semiconductor devices 40 and 45 which pass the test are used. Therefore, the yield of stacked semiconductor devices can be increased.

Since the semiconductor chip 1 is not arranged in a large region in the periphery of the semiconductor device 45, the strength of the semiconductor device 45, in use by itself, may be low. In this case, when the semiconductor devices 40 and 45 are fixed by the conductive ball 17 of the semiconductor device 40, the semiconductor devices 40 and 45 as a whole can assure strength in use. For this reason, it is understood that the chip size of the semiconductor chip 1 of the semiconductor device 40 and the chip size of the semiconductor chip 1 of the semiconductor device 45 are not affected by each other.

(Eighth Embodiment)

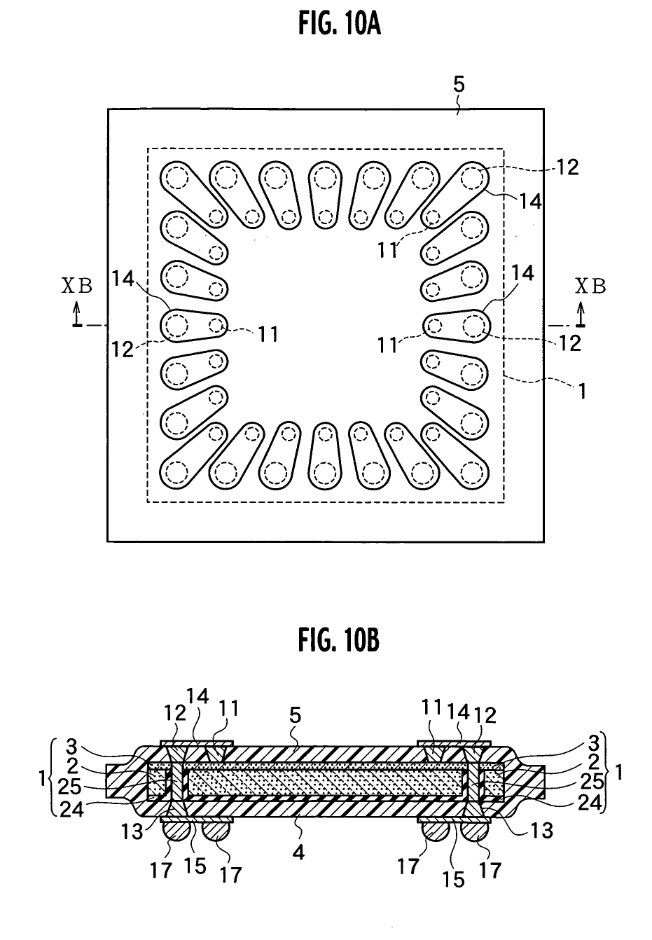

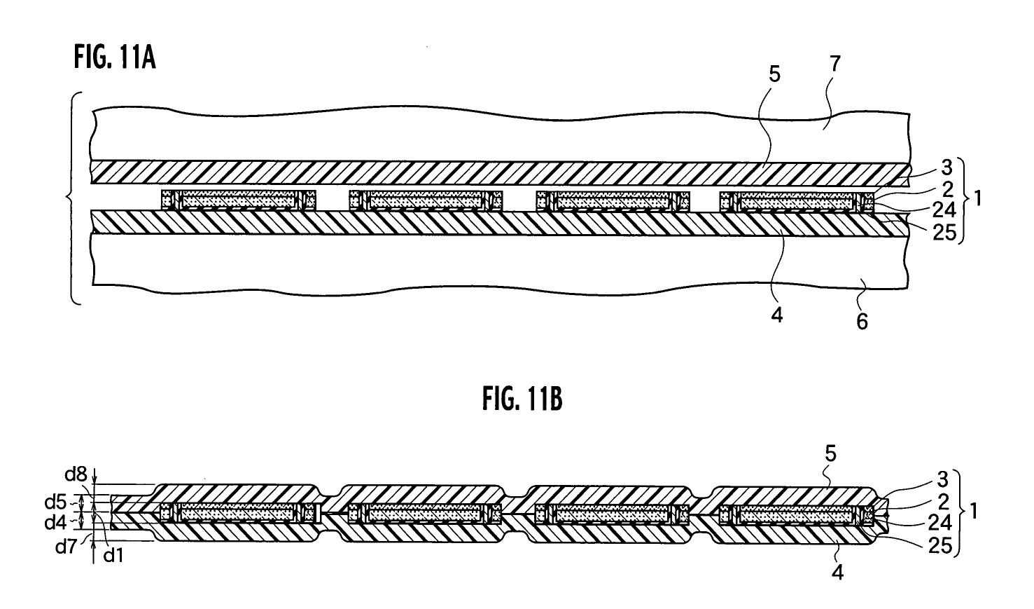

A semiconductor device according to the eighth embodiment of the present invention, as shown in FIGS. 10A and 10B, is different from the semiconductor device 33 according to the first embodiment in that through plugs 12, 13, and 25 penetrate the semiconductor chip 1.

The semiconductor chip 1 has a semiconductor substrate 2, a semiconductor element forming region 3, a conductive column 25, and an insulating film 24. The conductive column 25 extends from the top surface of the semiconductor substrate 2 to the bottom surface thereof. The conductive column 25 is electrically connected to the conductive columns 12 and 13. The insulating film 24 is formed between the semiconductor substrate 2 and the conductive column 25.

A method for manufacturing a semiconductor device according to the eighth embodiment of the present invention will be described below.

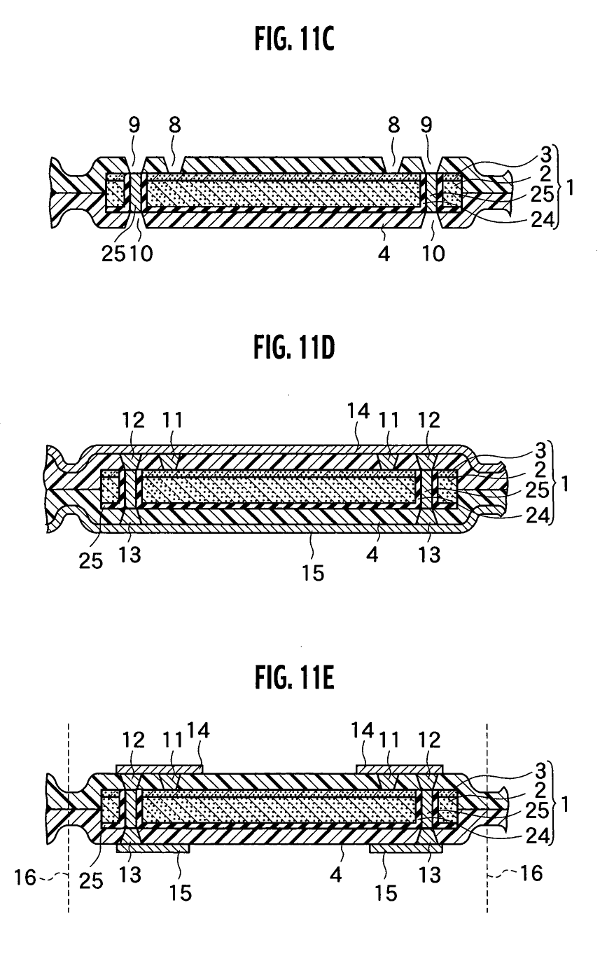

As shown in FIG. 11A, a bonding device indicated by reference numerals 6 and 7 having a pressure furnace may be used. The insulating film 4 serving as a stacking resin film for a buildup support substrate is placed on the sample table 6 of the bonding device. A plurality of semiconductor chips 1 are placed on the insulating film 4 such that the entire bottom surfaces of the semiconductor chips 1 are in contact with the insulating film 4. The insulating film 5 is placed on the plurality of the semiconductor chips 1 such that the entire top surfaces of the semiconductor chips 1 are in contact with the insulating film 5. As the insulating film 5, an insulating film made of the same material as that of the insulating film 4 and having a film thickness equal to that of the insulating film 4 is used. The press table 7 of the bonding device is arranged above the insulating film 5.

The insulating films 4 and 5 and the semiconductor chip 1 are compressed between the sample table 6 and the press table 7 in the pressure furnace of the bonding device. In this manner, as shown in FIG. 11B, the semiconductor chip 1 is laminated with the insulating films 4 and 5 from both the top and bottom surfaces. The entire bottom surface of the semiconductor chip 1 can be adhered to the insulating film 4. The insulating film 5 can be adhered to the entire top surface of the semiconductor chip 1 and the insulating film 4. The insulating films 4 and 5 are adhered to each other between the semiconductor chips 1.

Reference symbol d7 denotes a film thickness of the insulating film 4 where the semiconductor chip 1 is formed. Reference symbol d8 denotes a film thickness of the insulating film 5 where the semiconductor chip 1 is formed. Since uniform pressure acts on the entire lower surface of the insulating film 4 and the entire upper surface of the insulating film 5 in compression, the film thickness d7 of the insulating film 4 where the semiconductor chip 1 is formed is equal to the film thickness d4 of the insulating film 4 where no semiconductor chip 1 is formed. The film thickness d8 of the insulating film 5 where the semiconductor chip 1 is formed is equal to the film thickness d5 of the insulating film 5 where no semiconductor chip 1 is formed.

As the insulating film 5, an insulating film made of the same material as that of the insulating film 4 and having a film thickness equal to that of the insulating film 4 is used. For this reason, the film thicknesses d5 and d8 of the insulating film 5 and the film thicknesses d4 and d7 of the insulating film 4 are equal to each other. Therefore, the semiconductor chip 1 is not warped.

Resists are coated on both upper and lower surfaces of the resultant structure and patterned. The insulating layers 4 and 5 are etched by using the patterned resists as masks. As shown in FIG. 11C, holes 8 to 10 serving as via holes are formed. The hole 8 penetrates the insulating film 5. The hole 8 exposes the upper surface of the semiconductor chip 1 to the air. The hole 9 penetrates the insulating film 5 and is formed immediately above the conductive column 25. The hole 10 penetrates the insulating film 4 and is formed immediately below the conductive column 25. In this manner, through electrodes can be formed.

A conductive film is formed on the exposed surface by a plating method. For this reason, as shown in FIG. 11D, the conductive columns 11 to 13 can be buried in the holes 8 to 10. The wiring layer 14 can be formed on the upper surface of the insulating film 5. The wiring layer 15 can be formed on the lower surface of the insulating film 4.

Resists are coated on both upper and lower surfaces of the resultant structure and patterned. The wiring layers 14 and 15 are etched by using the patterned resists as masks. As shown in FIG. 11E, the wiring layers 14 and 15 having the patterned wiring layers can be formed. The wiring layers 14 and 15 may be formed by a semi-additive method. The insulating films 4 and 5 are cut at a cut line 16 to separate the plurality of semiconductor devices into independent pieces. Finally, as shown in FIG. 10B, a conductive ball 17 is formed under the wiring layer 15.

According to the method for manufacturing a semiconductor device according to the eighth embodiment, the same effect as that of the first embodiment can be achieved, a plurality of processes such as a buildup support substrate manufacturing process, a bump process, and an assembling process (flip chip or resin sealing), which are separately performed in the prior art, can be performed only once on all the units or devices of the sheets of the devices of the stacked insulating films 4 and 5 having a plurality of semiconductor chips 1. In this manner, the productivity, i.e., the yield of semiconductor devices is considerably improved. In particular, the method for manufacturing a semiconductor device according to the eighth embodiment can be applied to a case in which the insulating films 4 and 5 are not transformed in fluidity.

The present invention may be embodied in other specific forms without departing from the spirit or essential characteristics thereof. The embodiments are therefore to be considered in all respects as illustrative and not restrictive, the scope of the present invention being indicated by the appended claims rather than by the foregoing description, and all changes which come within the meaning and range of equivalency of the claims are therefore intended to be embraced therein.

What is claimed is:

1. A semiconductor device comprising:
a first insulating film having a first planar surface as a lower surface;
a first semiconductor chip disposed on the first insulating film;
a second insulating film disposed on the first semiconductor chip and the first insulating film, and having a second planar surface as an upper surface;
a first wiring layer disposed under the first planar surface;
a second wiring layer disposed on the second planar surface, and electrically connected to the first semiconductor chip;
a first conductive column penetrating the first insulating film and the second insulating film, configured to electrically connect the first wiring layer to the second wiring layer; and
a conductor penetrating the second insulating film, configured to electrically connect the first semiconductor chip to the second wiring layer.

2. The semiconductor device as claimed in claim 1, wherein the second planar surface is larger than an upper surface of the first semiconductor chip.

3. The semiconductor device as claimed in claim 1, wherein the first semiconductor chip has a semiconductor substrate, a second conductive column extending from a top surface of the semiconductor substrate to a bottom surface of the semiconductor substrate, and configured to electrically connect to the first conductive column, and a cylindrical insulating film formed between the semiconductor substrate and the second conductive column.

4. The semiconductor device as claimed in claim 1, wherein the first conductive column is adjacent to a side of the first semiconductor chip.

5. The semiconductor device as claimed in claim 1, further comprising a conductive ball configured to electrically connect to the first wiring layer.

6. The semiconductor device as claimed in claim 1, wherein a film thickness of the first insulating film under the fist semiconductor chip is equal to a film thickness of the second insulating film above the first semiconductor chip.

7. The semiconductor device as claimed in claim 1, further comprising:
a third insulating film disposed under the first insulating film and the first wiring layer, and having a third planar surface as a lower surface;
a third wiring layer disposed under the third planar surface, and configured to electrically connect to the first wiring layer;
a fourth insulating film disposed on the second insulating film and the second wiring layer, and having a fourth planar surface as an upper surface; and
a fourth wiring layer disposed on the fourth planar surface, and configured to electrically connect to the second wiring layer.

8. The semiconductor device as claimed in claim 7, wherein a film thickness of the third insulating film is equal to a film thickness of the fourth insulating film.

9. The semiconductor device as claimed in claim 1, further comprising:
a conductive ball configured to electrically connect to the second wiring layer;
a third insulating film having a third planar surface as a lower surface;
a third wiring layer disposed under the third planer surface and configured to electrically connect to the conductive ball;
a second semiconductor chip disposed on the third insulating film;
a fourth insulating film disposed on the second semiconductor chip and the third insulating film, and having a fourth planar surface as an upper surface;
a fourth wiring layer disposed on the fourth planar surface, and configured to electrically connect to the second semiconductor chip; and
a second conductive column penetrating the third insulating film and the fourth insulating film, and configured to electrically connect to the third wiring layer and the fourth wiring layer.

10. The semiconductor device as claimed in claim 1, wherein the first semiconductor chip has a semiconductor substrate, a second conductive column extending from the top surface of the semiconductor substrate to the bottom surface of the semiconductor substrate and configured to electrically connect to the first wiring layer and the second wiring layer, and a cylindrical insulating film disposed between the semiconductor substrate and the second conductive column.

11. A semiconductor device comprising:
a conductive plate having a first planar surface as an upper surface;
an adhesive layer disposed on the first planar surface;
a first semiconductor chip disposed on the adhesive layer;
a first insulating film disposed on the first semiconductor chip and the conductive plate, and having a second planar surface as an upper surface; and
a first wiring layer disposed on the second planar surface and configured to electrically connect to the first semiconductor chip.

12. The semiconductor device as claimed in claim 11, wherein the second planar surface is disposed above a side of the first semiconductor chip.

13. The semiconductor device as claimed in claim 11, further comprising a first conductive ball configured to electrically connect to the wiring layer.

14. The semiconductor device as claimed in claim 11, further comprising:
a second insulating film having a third planar surface as a lower surface;
a second wiring layer disposed under the third planar surface, and configured to electrically connect to the first conductive ball;
a second semiconductor chip disposed on the second insulating film, and configured to electrically connect to the second wiring layer;
a third insulating film disposed on the second semiconductor chip and the second insulating film, and having a fourth planar surface as an upper surface;
a third wiring layer disposed on the fourth planar surface; and
a first conductive column penetrating the second insulating film and the third insulating film, and configured to electrically connect to the second wiring layer and the third wiring layer.

15. A method for manufacturing a semiconductor device comprising:
adhering the entirety of a bottom surface of a semiconductor chip to a first insulating film, and adhering a second insulating film to the first insulating film and the entirety of a top surface of the semiconductor chip;
forming a first hole penetrating the second insulating film to expose the top surface of the semiconductor chip, and forming a second hole penetrating the first insulating film and the second insulating film;
burying a first conductor in the first hole, and burying a second conductor in the second hole; and
forming a first wiring layer configured to electrically connect to the second conductor and disposed on a surface of the first insulating film, and forming a second wiring layer configured to electrically connect to the first conductor and the second conductor and disposed on a surface of the second insulating film.

16. The method as claimed in claim 15, wherein the semiconductor chip is one of a plurality of semiconductor chips, and the method further comprises cutting the first insulating film and the second insulating film, and separating the plurality of semiconductor chips into individual chips after forming the first wiring layer.

17. The method as claimed in claim 15, wherein the semiconductor chip is one of a plurality of semiconductor chips, and the method further comprises disposing the first wiring layer electrically connected to one of the semiconductor chips above the second wiring layer electrically connected to another of the semiconductor chips, and electrically connecting the second wiring layer electrically connected to the another of the semiconductor chips and the first wiring layer electrically connected to the one of the semiconductor chips.

18. The method as claimed in claim 15, wherein, in adhering the second insulating film, an interval between a lower surface of the first insulating film and an upper surface of the second insulating film at a position where the first insulating film and the second insulating film interpose the semiconductor chip is equal to an interval between a lower surface of the first insulating film and an upper surface of the second insulating film at a position where the first insulating film and the second insulating film do not interpose the semiconductor chip.

19. The method as claimed in claim 15, wherein, in adhering the second insulating film, a film thickness of the first insulating film at a position where the first insulating film and the second insulating film interpose the semiconductor chip is thinner than a film thickness of the first insulating film at a position where the first insulating film and the second insulating film do not interpose the semiconductor chip.

20. A method for manufacturing a semiconductor device comprising:
adhering the entirety of a bottom surface of a semiconductor chip to a metal plate, and adhering a first insulating film to the metal plate and the entirety of a top surface of the semiconductor chip;
forming a hole penetrating the first insulating film to expose the top surface of the semiconductor chip;
burying a first conductor in the hole; and
forming a first wiring layer configured to electrically connect to the first conductor and disposed on a surface of the first insulating film.
